(19) United States
(12) Patent Application Publication
(10) Pub. No.: US 2022/0196723 A1
(43) Pub. Date: Jun. 23, 2022

(54) SYSTEM AND METHOD FOR AUTOMATICALLY IDENTIFYING DEFECT-BASED TEST COVERAGE GAPS IN SEMICONDUCTOR DEVICES

(71) Applicant: KLA Corporation, Milpitas, CA (US)

(72) Inventors: David W. Price, Austin, TX (US); Robert J. Rathert, Mechanicsville, VA (US); Chet V. Lenox, Lexington, TX (US); Kara L. Sherman, San Jose, CA (US); Teng Song Lim, Punggol (SG); Thomas Groos, Mengerskirchen (DE); Mike Von Den Hoff, Muenchen (DE); Oreste Donzella, San Ramon, CA (US); Narayani Narasimhan, New Delhi (IN); Barry Saville, Gansevoort (GB); Justin Lach, Portage, MI (US); John Robinson, Austin, TX (US)

(21) Appl. No.: 17/321,263

(22) Filed: May 14, 2021

Related U.S. Application Data
(60) Provisional application No. 63/144,997, filed on Feb. 3, 2021.

(30) Foreign Application Priority Data
Dec. 18, 2020 (IN) 202041055201

(51) Int. Cl. G01R 31/26; H01L 21/66

(52) U.S. Cl. CPC G01R 31/2601; H01L 22/20

(57) ABSTRACT

Automatically identifying defect-based test coverage gaps in semiconductor devices includes determining a plurality of apparent killer defects on one or more semiconductor devices with a plurality of semiconductor dies based on characterization measurements of the one or more semiconductor devices acquired by one or more semiconductor fabrication subsystems, determining at least one semiconductor die which passes at least one test based on test measurements acquired by one or more test tool subsystems, correlate the characterization measurements with the test measurements to determine at least one apparent killer defect on the at least one semiconductor die which passes the at least one test, and determining one or more gap areas on the one or more semiconductor devices for defect-based test coverage based on the at least one apparent killer defect on the at least one semiconductor die which passes the at least one test.

### CROSS-REFERENCE TO RELATED APPLICATIONS

The present application claims priority to India Provisional Application Serial Number 202041055201, filed Dec. 18, 2020, and priority to U.S. Provisional Application Ser. No. 63/144,997, filed on Feb. 3, 2021, both of which are incorporated herein by reference in the entirety.

### TECHNICAL FIELD

The present disclosure relates generally to semiconductor devices and, more particularly, to systems and methods for automatically identifying defect-based test coverage gaps in semiconductor devices.

### BACKGROUND

Fabrication of semiconductor devices may typically require hundreds or thousands of processing steps to form a functioning device. Over the course of these processing steps, various inspection and/or metrology measurements may be performed to identify defects and/or monitor various parameters on the devices. Electrical testing may also be performed to verify or assess the functionality of the device. However, while some detected defects and metrology errors may be so significant as to clearly indicate a device failure, lesser variations may cause early reliability failures of the device after exposure to their working environment. Risk-averse users of semiconductor devices, such as automotive, military, aeronautical, and medical applications, are beginning to look for failure rates in the parts-per-billion (PPB) range, exceeding current parts-per-million (PPM) levels. Recognizing and controlling reliability defects is key to meeting these industry requirements, as the need for semiconductor devices in automotive, military, aeronautical, and medical applications continues to increase. Therefore, it may be desirable to provide systems and methods for reliability defect detection.

### SUMMARY

A system is disclosed, in accordance with one or more embodiments of the present disclosure. In one illustrative embodiment, the system includes a controller communicatively coupled to one or more semiconductor fabrication subsystems and one or more test tool subsystems. In another illustrative embodiment, the controller includes one or more processors configured to execute program instructions causing the one or more processors to determine, via a characterization subsystem, a plurality of apparent killer defects on one or more semiconductor devices based on characterization measurements of the one or more semiconductor devices acquired by the one or more semiconductor fabrication subsystems. In another illustrative embodiment, the one or more semiconductor devices include a plurality of semiconductor dies. In another illustrative embodiment, the controller includes one or more processors configured to execute program instructions causing the one or more processors to determine, via a testing subsystem, at least one semiconductor die of the plurality of semiconductor dies which passes at least one test of a plurality of tests based on test measurements acquired by the one or more test tool subsystems. In another illustrative embodiment, the controller includes one or more processors configured to execute program instructions causing the one or more processors to correlate, via a correlation subsystem, the characterization measurements with the test measurements to determine at least one apparent killer defect of the plurality of apparent killer defects on the at least one semiconductor die of the plurality of semiconductor dies which passes the at least one test of the plurality of tests. In another illustrative embodiment, the controller includes one or more processors configured to execute program instructions causing the one or more processors to determine, via a localization subsystem, one or more gap areas on the one or more semiconductor devices for defect-based test coverage based on the at least one apparent killer defect on the at least one semiconductor die of the plurality of semiconductor dies which passes the at least one test of the plurality of tests.

A method is disclosed, in accordance with one or more embodiments of the present disclosure. In one illustrative embodiment, the method may include, but is not limited to, determining, via a characterization subsystem of a controller, a plurality of apparent killer defects on one or more semiconductor devices based on characterization measurements of the one or more semiconductor devices acquired by one or more semiconductor fabrication subsystems. In another illustrative embodiment, one or more semiconductor devices include a plurality of semiconductor dies. In another illustrative embodiment, the method may include, but is not limited to, determining, via a testing subsystem of the controller, at least one semiconductor die of the plurality of semiconductor dies which passes at least one test of a plurality of tests based on test measurements acquired by one or more test tool subsystems. In another illustrative embodiment, the method may include, but is not limited to, correlating, via a correlation subsystem of the controller, the characterization measurements with the test measurements to determine at least one apparent killer defect of the plurality of apparent killer defects on the at least one semiconductor die of the plurality of semiconductor dies which passes the at least one test of the plurality of tests. In another illustrative embodiment, the method may include, but is not limited to, determining, via a localization subsystem of the controller, one or more gap areas on the one or more semiconductor devices for defect-based test coverage based on the at least one apparent killer defect on the at least one semiconductor die of the plurality of semiconductor dies which passes the at least one test of the plurality of tests.

A system is disclosed, in accordance with one or more embodiments of the present disclosure. In one illustrative embodiment, the system includes one or more semiconductor fabrication subsystems. In another illustrative embodiment, the system includes one or more test tool subsystems. In another illustrative embodiment, the system includes a controller communicatively coupled to the one or more semiconductor fabrication subsystems and the one or more test tool subsystems. In another illustrative embodiment, the controller includes one or more processors configured to execute program instructions causing the one or more processors to determine, via a characterization subsystem, a plurality of apparent killer defects on one or more semiconductor devices based on characterization measurements of the one or more semiconductor devices acquired by the one or more semiconductor fabrication subsystems. In another illustrate embodiment, one or more semiconductor devices include a plurality of semiconductor dies. In another illustrative embodiment, the controller includes one or more processors configured to execute program instructions causing the one or more processors to determine, via a testing subsystem, at least one semiconductor die of the plurality of semiconductor dies which passes at least one test of a plurality of tests based on test measurements acquired by the one or more test tool subsystems. In another illustrative embodiment, the controller includes one or more processors configured to execute program instructions causing the one or more processors to correlate, via a correlation subsystem, the characterization measurements with the test measurements to determine at least one apparent killer defect of the plurality of apparent killer defects on the at least one semiconductor die of the plurality of semiconductor dies which passes the at least one test of the plurality of tests. In another illustrative embodiment, the controller includes one or more processors configured to execute program instructions causing the one or more processors to determine, via a localization subsystem, one or more gap areas on the one or more semiconductor devices for defect-based test coverage based on the at least one apparent killer defect on the at least one semiconductor die of the plurality of semiconductor dies which passes the at least one test of the plurality of tests.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1 is a flow diagram illustrating steps performed in a method or process for automatically identifying defect-based test coverage gaps in semiconductor devices, in accordance with one or more embodiments of the present disclosure;

FIG. 2 is a block diagram view of a system for automatically identifying defect-based test coverage gaps in semiconductor devices, in accordance with one or more embodiments of the present disclosure;

FIG. 3A is a conceptual illustration of a killer defect in a semiconductor die that passes testing, in accordance with one or more embodiments of the present disclosure;

FIG. 3B is a conceptual illustration of a killer defect in a semiconductor die that passes testing, in accordance with one or more embodiments of the present disclosure;

FIG. 3C is a conceptual illustration of a killer defect in a semiconductor die that passes testing, in accordance with one or more embodiments of the present disclosure;

FIG. 3D is a conceptual illustration of a killer defect in a semiconductor die that passes testing, in accordance with one or more embodiments of the present disclosure;

FIG. 4A is a conceptual illustration of a semiconductor die layout, in accordance with one or more embodiments of the present disclosure;

FIG. 4B is a conceptual illustration of a semiconductor die layout overlaid with killer defects, in accordance with one or more embodiments of the present disclosure;

FIG. 4C is a conceptual illustration of a semiconductor die layout overlaid with killer defects including a potential defect-based test coverage gap area, in accordance with one or more embodiments of the present disclosure;

FIG. 5A is a chart illustrating test cover gap trend over time, in accordance with one or more embodiments of the present disclosure;

FIG. 5B is a chart illustrating test cover gap trend by product, in accordance with one or more embodiments of the present disclosure;

FIG. 6 is a flow diagram illustrating steps performed in a method or process for fabricating semiconductor devices, in accordance with one or more embodiments of the present disclosure;

FIG. 7A is a block diagram view of a system for fabricating semiconductor devices, in accordance with one or more embodiments of the present disclosure; and

FIG. 7B is a block diagram view of a system for fabricating semiconductor devices, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Defects arising during the manufacturing process may have a wide range of impacts on the performance of the device in the field. For example, “killer” defects may result in immediate device failure. By way of another example, minor defects may have little or no impact on the performance of the device throughout the device lifetime. By way of another example, a class of defects known as latent reliability defects (LRD) may not lead to failure during manufacturing/testing or may not lead to immediate device failure during operation, but may lead to early-life failure of the device during operation when used in a working environment. It is noted herein the terms “manufacturing process” and “fabrication process” may be considered equivalent, along with respective variants of the terms (e.g., “manufacturing line” and “fabrication line”, and the like), for purposes of the present disclosure.

Killer defects may occur in known or unknown locations within designs. The unknown locations are particularly problematic where they have a susceptibility to reliability escapes from killer defects in test gaps. Developments associated with the implementation of Inline Defect Part Average Testing (I-PAT) indicate a relatively large percentage of reliability escapes may be due to apparent killer defects in test coverage gaps. In an instance where there is a reliability escape, a semiconductor device may be functionally dead after processing but the device maker is unable to make this determination due to limitations in testing. Examples implementing I-PAT may be found in U.S. Pat. No. 10,761,128, issued on Sep. 9, 2020, and U.S. patent application Ser. No. 17/101,856, filed on Nov. 23, 2020, which are each incorporated herein in the entirety.

Test coverage gaps may stem from one of a number of sources. For example, test coverage gaps may occur in areas of the semiconductor device which are untestable due to the logic layout of the device. By way of another example, test coverage gaps may occur in areas of the semiconductor device which are practically too difficult to comprehensively measure (e.g., analog circuits, or the like) due to the failure identification not merely consisting of being in the correct on/off state. By way of another example, test coverage gaps may occur in areas of the semiconductor device which are not tested due to cost considerations associated with the increasing expense of test with test coverage.

Old methods or processes for identifying high-risk areas for test coverage escapes on a semiconductor device may generally allow semiconductor fabricators to achieve part-per-million (PPM) levels of baseline reliability defect control, depending on chip complexity and size. However, select semiconductor fabricators (e.g., automotive semiconductor fabricators, military semiconductor fabricators, aeronautical semiconductor fabricators, medical applications semiconductor fabricators, or the like) are aggressively pursuing new and innovative methods to identify sources of reliability failures, to achieve part-per-billion (PPB) level of baseline reliability defect control.

For example, old methods or processes include predictive methods such as test simulation software packages. The predictive methods, however, have varying degrees of efficacy that is highly device dependent. For instance, analog devices are much harder to predict than digital devices. In addition, certain areas of the circuit layout are often deemed “untestable” regardless of how much test time is allocated. Furthermore, predictive methods are, by their nature, unable to identify unexpected areas of test coverage gaps.

By way of another example, old methods or processes also include tribal knowledge based on past semiconductor devices. Tribal knowledge based on past devices generally provides a good starting point for device makers to design an appropriate test strategy. However, this may not be comprehensive or quantitative.

By way of another example, old methods or processes also include physical failure analysis (PFA) from stress-testing or field reliability returns. For example, automotive semiconductor fabricators may be required to perform PFA of stress-tested die or field reliability returns. The latter may be returns from a Tier 1 component supplier, assembly at the automotive OEM, or warranty field returns from the end consumer. While a necessary task, PFA does not provide enough information to create a comprehensive picture of test coverage gaps for a device. For example, there may be a lack of statistical significance, as the PPM number of failures is so small that it is difficult to arrive at a comprehensive understanding of the baseline reliability pareto from a handful of field returns, which results in the semiconductor fabricator only seeing a few pieces of the puzzle. By way of another example, field returns generally provide information that reflects the semiconductor fabricator's reliability problems at the time the failing device was manufactured, which could be several years in the past and no longer relevant for the current design. By way of another example, physical failure analysis is expensive, time-consuming, and frequently inconclusive or incorrect. By way of another example, the root cause of the reliability failure is frequently destroyed, either by the activation of the defect or by collateral damage from the PFA delaying processes.

Embodiments of the present disclosure are directed to systems and methods for automatically identifying defect-based test coverage gaps in semiconductor devices. In particular, embodiments of the present disclosure are directed to allowing for the automatic identification of previously unknown locations within designs which have an elevated susceptibility to reliability escapes from killer defects in test gaps. In addition, embodiments of the present disclosure are directed to using empirical defect data to systematically identify test coverage gaps. Further, embodiments of the present disclosure are directed to providing new metrics to quantify the risk of reliability escapes on a device-by-device basis or over time as improvements are made. Further, embodiments of the present disclosure are directed to providing new metrics and/or charting to demonstrate continuous improvement, evaluate the effectiveness of test program changes, and quantify test gap differences on a device-by-device basis or between different devices in the product portfolio over time as improvements are made.

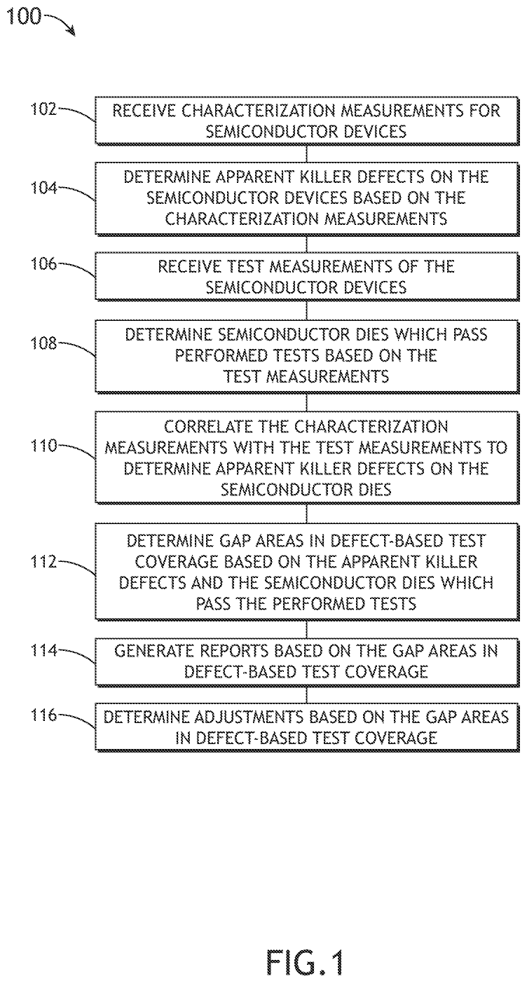

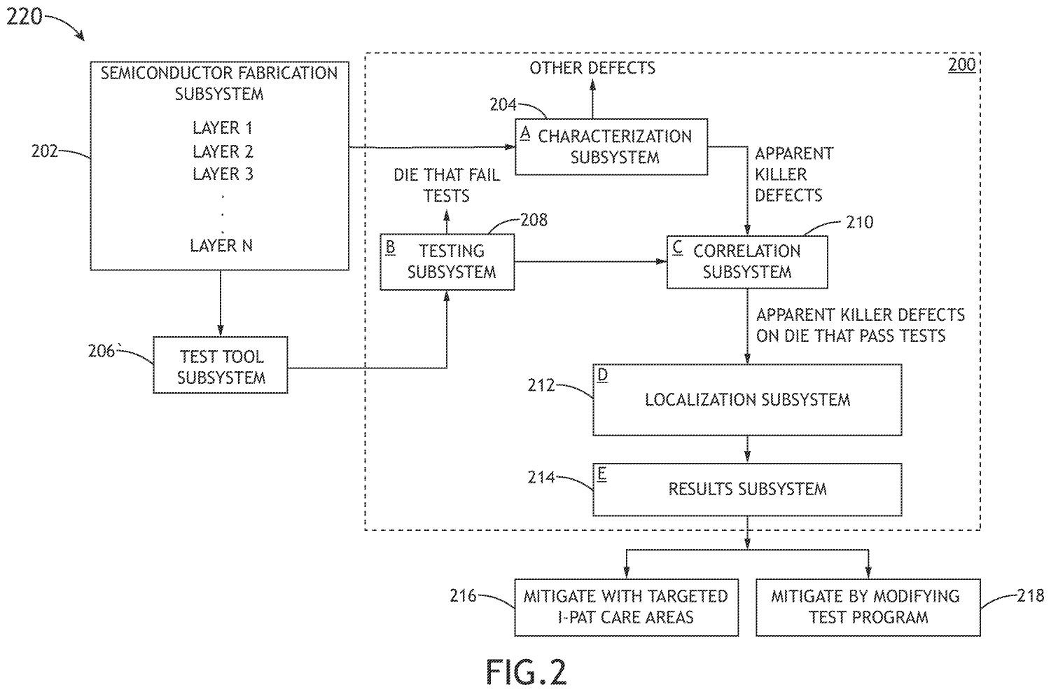

FIG. 1 illustrates a method or process 100 for automatically identifying defect-based test coverage gaps in semiconductor devices, in accordance with one or more embodiments of the present disclosure. FIG. 2 illustrates a block diagram view of a system 200 for automatically identifying defect-based test coverage gaps in semiconductor devices, in accordance with one or more embodiments of the present disclosure. It is noted herein that the steps of method or process 100 may be implemented all or in part by the system 200 illustrated in FIG. 2. It is further recognized, however, that the method or process 100 is not limited to the system 200 illustrated in FIG. 2 in that additional or alternative system-level embodiments may carry out all or part of the steps of method or process 100.

In a step 102, characterization measurements for one or more semiconductor devices are received. In some embodiments, the system 200 receives information outputted by one or more semiconductor fabrication subsystems 202. The characterization measurements may be performed during the fabrication of the one or more semiconductor devices. For example, the one or more semiconductor fabrication subsystems 202 may include, but are not limited to, one or more process tools configured to manufacture semiconductor devices including 1, 2, . . . N number of layers fabricated following a number (e.g., tens, hundreds, thousands) of steps performed by a number of fabrication processes. By way of another example, the one or more semiconductor fabrication subsystems 202 may include, but are not limited to, one or more inline defect inspection and/or metrology tools configured to characterize the semiconductor devices. For instance, the one or more outputs may include, but are not limited to, baseline inspections (e.g., sampling-based inspections), screening inspections at key semiconductor device layers, or the like. For purposes of the present disclosure, “characterization” may refer to either inline defect inspection or inline metrology measurements.

In a step 104, one or more apparent killer defects on the one or more semiconductor devices are determined based on the characterization measurements of the one or more semiconductor devices. In some embodiments, the system 200 includes a characterization subsystem 204, or subsystem A. The characterization subsystem 204 may receive the information outputted by the one or more semiconductor fabrication subsystems 202 generated following the characterizing of the semiconductor devices. The characterization subsystem 204 may determine one or more apparent killer defects from the information, by applying one or more processes to the received inline defect data to separate defects which are apparent killer defects from those which have a lower probability of impacting device performance. For example, the characterization subsystem 204 may implement deterministic and/or statistical thresholding techniques. By way of another example, advanced deep learning or machine learning techniques may be implemented due to the potentially large data set and/or potential variation in defectivity. In general, the machine learning techniques may be any technique known in the art including, but not limited to, supervised learning, unsupervised learning, or other learning-based processes such as, but not limited to, linear regression, neural networks or deep neural networks, heuristic-based model, or the like. It is noted herein semiconductor dies or wafers without apparent killer defects may be flagged for further review (e.g., for other types of defects).

In a step 106, test measurements of the one or more semiconductor devices are received. In some embodiments, the system 200 receives information outputted by one or more test tool subsystems 206. The test measurements may be acquired for the one or more semiconductor devices. For example, the one or more test tool subsystems 206 may include, but are not limited to, one or more electrical test tools, one or more stress test tools, or the like. The one or more test tool subsystems 206 may be configured to test semiconductor devices fabricated by one or more semiconductor fabrication processes performed via the one or more semiconductor fabrication subsystems 202. For purposes of the present disclosure, “test” may be understood as referring to the process of electrically evaluating the device functionality at the conclusion of a fabrication manufacturing process (e.g., electrical wafer sort (EWS) processes, or the like), the conclusion of packaging (e.g., unit probe processes, class probe processes, or the like), and/or at the conclusion of final tests (e.g., after burn-in processes and other quality check processes). It is noted herein non-passing semiconductor dies or wafers may be isolated from passing semiconductor dies or wafers, and/or flagged for further testing.

In a step 108, one or more semiconductor dies which pass one or more performed tests are determined based on the test measurements of the one or more semiconductor devices. In some embodiments, the system 200 includes a test subsystem 208, or subsystem B. The test subsystem 208 may receive the information outputted by the one or more test tool subsystems 206 following the testing of the semiconductor devices produced by one or more semiconductor fabrication processes performed via the one or more semiconductor fabrication subsystems 202. The test subsystem 208 may separate semiconductor die that pass performed tests from those that fail performed tests (e.g., the performed tests including, but not limited to, probing, electrical testing, stress testing, or the like). For example, the semiconductor die may be given bin numbers during fabrication, and subsystem B may separate semiconductor die that pass performed tests from those that fail performed tests based on the bin numbers. For instance, only semiconductor die that pass all performed tests may be accepted by the test subsystem 208. In the alternative, any semiconductor die that pass a select subset of the performed tests may be accepted by the test subsystem 208, where the select subset is less than the entire set of performed tests. It is noted herein non-passing semiconductor dies or wafers may be removed from consideration (e.g., discarded) and/or flagged for further testing.

In a step 110, the characterization measurements are correlated with the test measurements to determine one or more apparent killer defects on the one or more semiconductor dies of the one or more semiconductor devices which pass the one or more performed tests. In some embodiments, the system 200 includes a correlation subsystem 210, or subsystem C. The correlation subsystem 210 may receive information outputted by the characterization subsystem 204 about the apparent killer defects. The correlation subsystem 210 may receive information outputted by the test subsystem 208 about the semiconductor die that pass the select subset or all of the performed tests. The correlation subsystem 210 may correlate the information outputted by the characterization subsystem 204 with the information outputted by the test subsystem 208 to determine a subpopulation of apparent killer defects that exist on semiconductor die which pass the select subset or all of the performed tests.

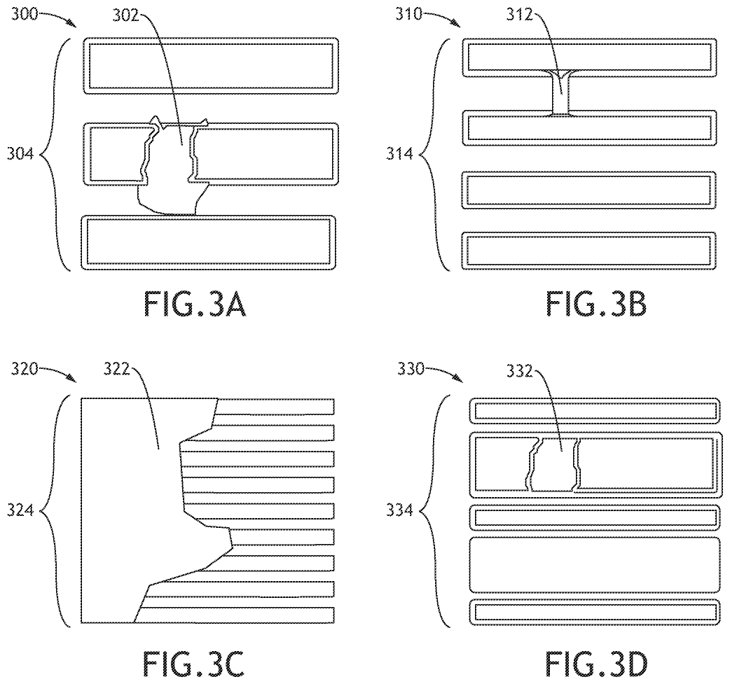

FIGS. 3A-3D illustrate conceptual illustrations of killer defects in semiconductor die that may pass the select subset or all of the tests performed by the one or more test tool subsystems 206, in accordance with one or more embodiments of the present disclosure. In FIG. 3A, image 300 illustrates an embedded particle 302 within a pattern 304. In FIG. 3B, image 310 illustrates a shorting bridge 312 within a pattern 314. In FIG. 3C, image 320 illustrates an instance 322 of copper plating under-polish proximate to a pattern 324. In FIG. 3D, image 330 illustrates a surface void 332 within a pattern 334.

In a step 112, one or more gap areas for defect-based test coverage are determined based on the one or more apparent killer defects on the one or more semiconductor dies of the one or more semiconductor devices which pass the one or more performed tests. In some embodiments, the system 200 includes a localization subsystem 212, or subsystem D. The localization subsystem 212 may receive information outputted by the correlation subsystem 210 about the subpopulation of apparent killer defects that exist on semiconductor die which pass the select subset or all of the performed tests. The gap areas in the defect-based test coverage where the semiconductor dies are not being adequately stressed to determine defects may be determined by the system 200. The localization subsystem 212 may analyze the location and frequency of the apparent killer defects in semiconductor die that pass the select subset or all of the performed tests. For example, the localization subsystem 212 may determine the systematic spreading of one or multiple instances throughout the semiconductor dies of the gap area in the defect-based test coverage.

In a step 114, one or more reports are generated for the one or more gap areas in defect-based test coverage on the one or more semiconductor devices. In some embodiments, the system 200 includes a results subsystem 214, or subsystem E. The results subsystem 214 may receive information outputted by the localization subsystem 212 about the location and/or frequency of the apparent killer defects in semiconductor die that pass the select subset or all of the performed tests. The results subsystem 214 may prepare reports including one or more metrics and/or one or more charting functions to render results into a form configured to assist semiconductor fabricators to take corrective action and/or evaluate the effectiveness of test program changes. For example, examples of corrective action may include, but are not limited to, temporary mitigation of a test gap through inspection screening (e.g., I-PAT, or the like) improvements caused by adjustments of the testing programs to provide greater coverage of the determined gap areas in the defect-based test coverage, or the like.

Examples implementing I-PAT may be found in U.S. Pat. No. 10,761,128, issued on Sep. 9, 2020, and U.S. patent application Ser. No. 17/101,856, filed on Nov. 23, 2020, each previously incorporated herein in the entirety. The examples provided in the incorporated patent and application are focused on identifying specific die at elevated risk to test coverage gaps for the purpose of product dispositioning (e.g., “screening”). It is noted herein, however, the present disclosure is directed to automatically identifying systematically at-risk areas of a semiconductor device for the purpose of improving the innate reliability of all chips for that semiconductor device and/or to direct mitigation efforts, and may not require screening data as input. In this regard, I-PAT may be implemented in the present disclosure, but is not required.

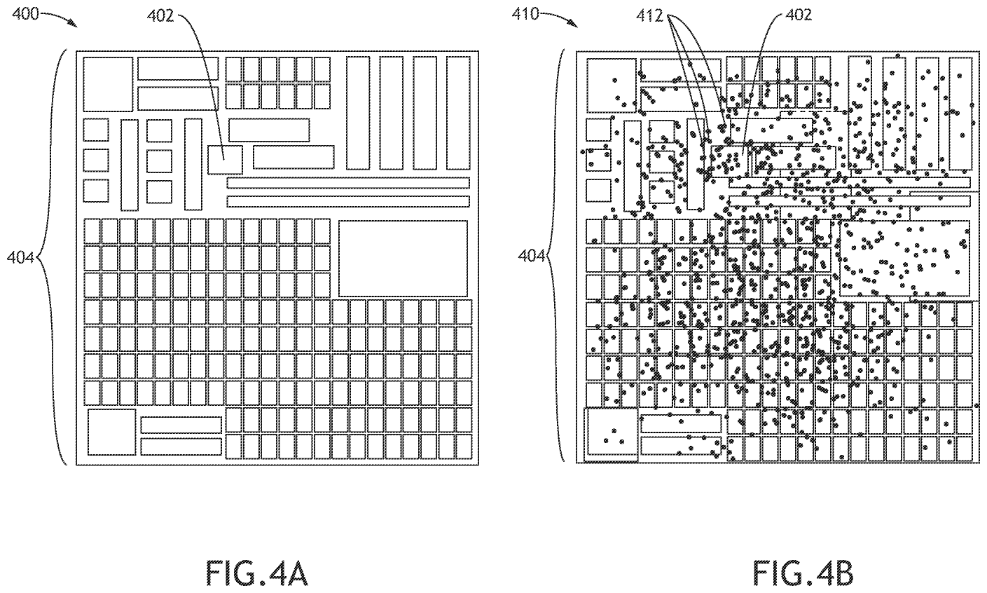

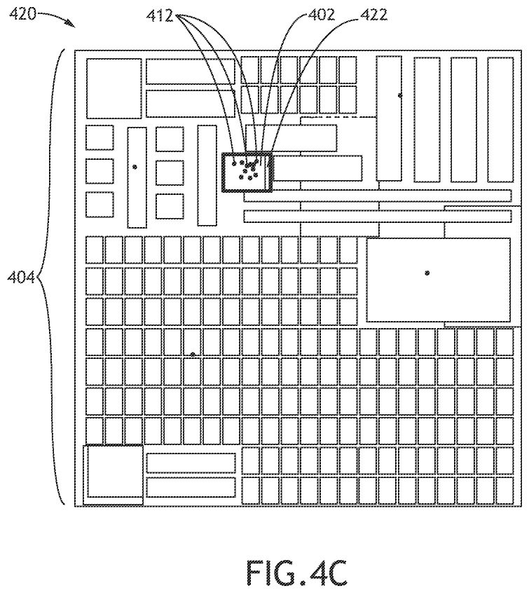

FIGS. 4A-4C illustrate conceptual illustrations of outputs from the results subsystem 214, in accordance with one or more embodiments of the present disclosure.

In FIG. 4A, image 400 illustrates one or more functional semiconductor die blocks 402 within a semiconductor die layout 404.

In FIG. 4B, image 410 illustrates one or more apparent killer defects 412 from all semiconductor die being analyzed following the select subset or all of the performed tests, where the one or more apparent killer defects 412 are overlaid on the one or more functional semiconductor die blocks 402 within the semiconductor die layout 404. For example, the image 410 may be representative of the apparent killer defects as determined by the characterization subsystem 204.

In FIG. 4C, image 420 illustrates one or more apparent killer defects 412 which passed the select subset or all of the performed tests within a gap area 422 in the defect-based test coverage, where the gap area 422 is overlaid on the one or more functional semiconductor die blocks 402 within the semiconductor die layout 404. For example, the image 420 may be representative of the gap areas 422 as determined by the correlation subsystem 210.

It is noted herein exact layout in and/or configuration of the images 400, 410, 420 are provided only for illustrative purposes. For example, the exact layout of the semiconductor die blocks 402 may be different than as illustrated in FIGS. 4A-4C. By way of another example, the graphic illustration of the apparent killer defects 412 and/or the gap areas 422 may be different than as illustrated in FIGS. 4B and 4C. Therefore, the above description should not be interpreted as a limitation on the scope of the present disclosure but merely an illustration.

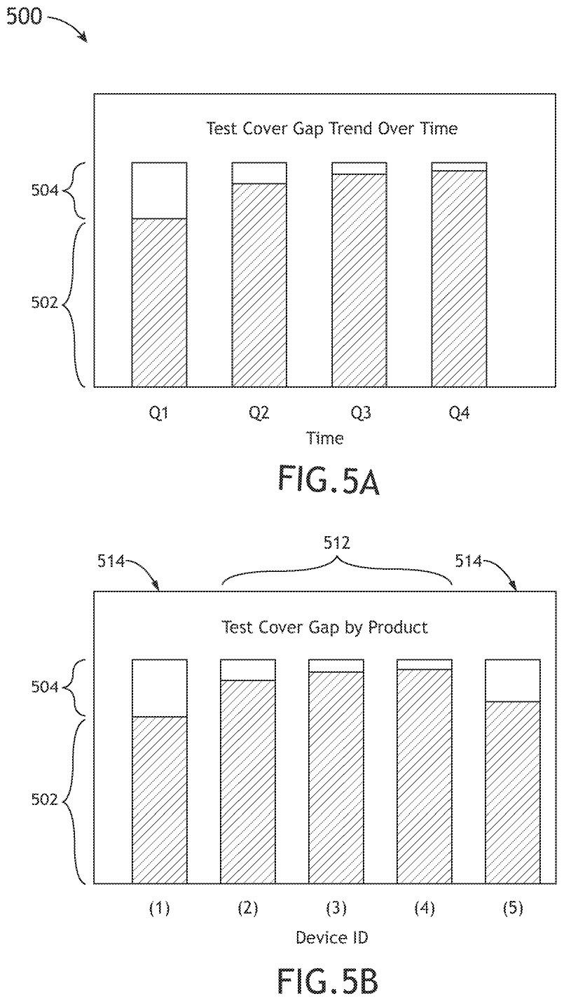

FIGS. 5A-5B illustrate generated metrics in the form of graphical outputs from the results subsystem 214 to demonstrate improvement of the semiconductor devices over time, in accordance with one or more embodiments of the present disclosure.

In FIG. 5A, chart 500 illustrates a particular tested semiconductor device design separated into a passing percentage 502 and a failing percentage 504 as compared to a range of time, where the failing percentage may represent potential gap areas in the defect-based test coverage. For example, the time range may be quarters, months, weeks, days, or the like. As illustrated in FIG. 5A, the test cover gap trend over time may improve (e.g., the ratio between the passing percentage 502 and the failing percentage 504 increases) as mitigating steps are taken to adjust the fabrication, characterizing, and/or testing of the semiconductor devices.

In FIG. 5B, chart 510 illustrates multiple different tested semiconductor device designs (1)-(5) across a product line or portfolio separated into a passing percentage 502 and a failing percentage 504 at a particular moment in time and/or for a range of time, where the failing percentage may represent potential gap areas in the defect-based test coverage. As illustrated in FIG. 5B, select semiconductor devices (e.g., devices (2)-(4)) may be separated out for use in a higher-threshold environment (e.g., automobiles, or the like requiring failure rates in a part-per-billion (PPB) range), while other semiconductor devices (e.g., devices (1) and (5)) may be separated out for use in a lower-threshold environment (e.g., televisions, smartphones, or the like requiring failure rates a part-per-million (PPM) range).

It is noted herein exact layout in and/or configuration of the charts 500, 510 are provided only for illustrative purposes. For example, the charts 500, 510 may be a different type of data display tool other than the bar chart (e.g., line chart, scatter plot, or other graphic) than as illustrated in FIGS. 5A and 5B. By way of another example, the charts 500, 510 may provide different information than as illustrated in FIGS. 5A and 5B. Therefore, the above description should not be interpreted as a limitation on the scope of the present disclosure but merely an illustration.

Although embodiments of the present disclosure illustrate the subsystems 204, 208, 210, 212, 214 being separate or standalone subsystems within the system 200, it is noted herein one or more of the subsystems 204, 208, 210, 212, 214 may be combined or integrated subsystems. Therefore, the above description should not be interpreted as a limitation on the scope of the present disclosure but merely an illustration.

In a step 116, one or more adjustments are determined for at least one of the fabrication, characterizing, or testing of the semiconductor devices based on the one or more gap areas on the one or more semiconductor devices for defect-based test coverage. In some embodiments, the system 200 may output information to outside systems or subsystems, where the information includes the corrective action to modify the fabrication, characterizing, and/or testing of the semiconductor devices. For example, a set of mitigating steps 216 may include targeting care areas (e.g., I-PAT care areas, or the like) provided in a feed forward loop to the outside systems or subsystems. For instance, the targeted care areas may include a detailed or fine-tuned inspection (e.g., generated via one or more control signals) to ink or scrap semiconductor die. By way of another example, a set of mitigating steps 218 may include modifications to fabrication processes or methods, characterization processes or methods, test processes or methods, or the like provided in a feedback loop to the outside systems or subsystems. For instance, the fabrication processes or methods, characterization processes or methods, test processes or methods, or the like may be adjusted (e.g., via one or more control signals) based on the determined gap areas in the defect-based test coverage. It is noted herein either or both of the sets of mitigating steps 216, 218 may be performed separately as standalone processes, the sets of mitigating steps 216, 218 may be performed in any sequential order, or the sets of mitigating steps 216, 218 may be performed simultaneously.

In some embodiments, the system 200, the one or more semiconductor fabrication subsystems 202, and the one or more test tool subsystems 206 are portions of a semiconductor device fabrication and defect-based test coverage gap identification system 220, for purposes of the present disclosure.

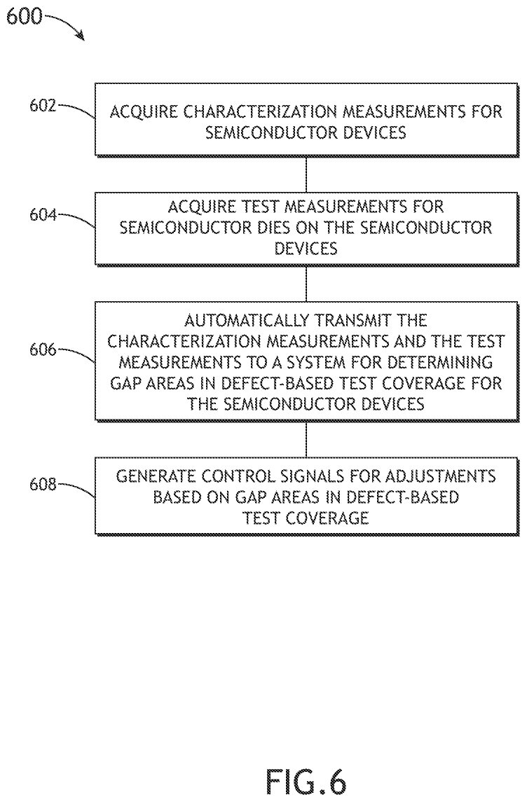

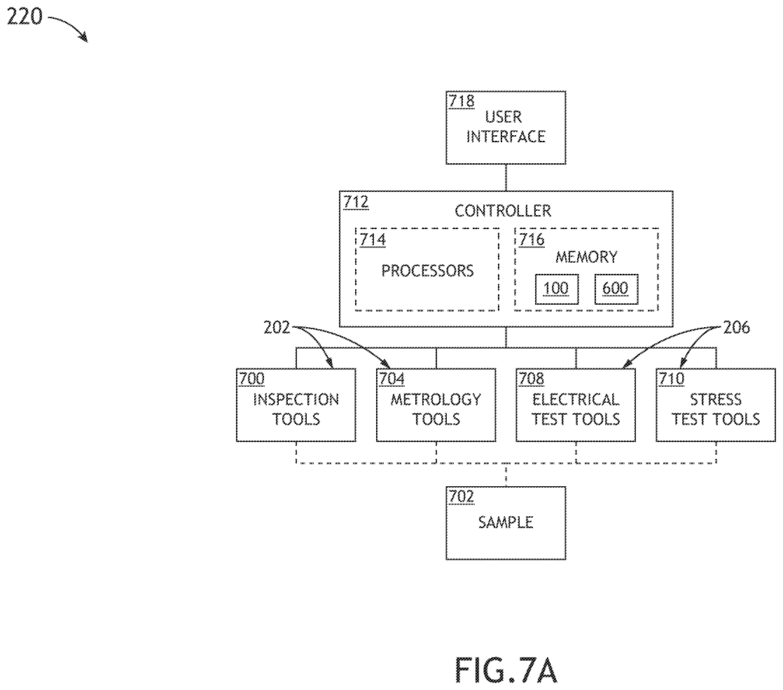

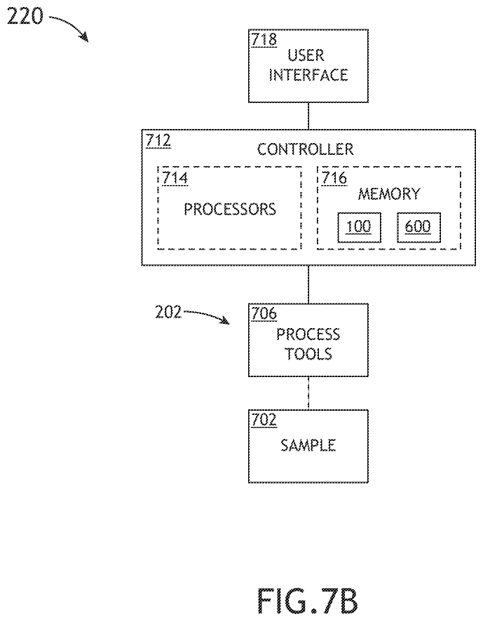

FIG. 6 illustrates a method or process 600 for automatically identifying defect-based test coverage gaps in semiconductor devices, in accordance with one or more embodiments of the present disclosure. FIGS. 7A and 7B illustrate block diagrams of the semiconductor device fabrication and defect-based test coverage gap identification system 220, or “system 220”, in accordance with one or more embodiments of the present disclosure. It is noted herein the system 220 may be configured to perform processing steps to fabricate and/or analyze semiconductor dies, as described throughout the present disclosure. In addition, it is noted herein that the steps of method or process 600 may be implemented all or in part by the system 220 illustrated in FIG. 7. It is further recognized, however, that the method or process 600 is not limited to the system 220 illustrated in FIG. 7 in that additional or alternative system-level embodiments may carry out all or part of the steps of method or process 600.

In a step 602, characterization measurements are acquired for one or more semiconductor devices. In some embodiments, the system 220 includes the one or more semiconductor fabrication subsystems 202.

In one non-limiting example, the one or more semiconductor fabrication subsystems 202 may include at least one inspection tool 700 (e.g., an inline sample analysis tool) for detecting defects in one or more layers of a sample 702. The system 220 may generally include any number or type of inspection tools 700. For example, an inspection tool 700 may include an optical inspection tool configured to detect defects based on interrogation of the sample 702 with light from any source such as, but not limited to, a laser source, a lamp source, an X-ray source, or a broadband plasma source. By way of another example, an inspection tool 700 may include a particle-beam inspection tool configured to detect defects based on interrogation of the sample with one or more particle beams such as, but not limited to, an electron beam, an ion beam, or a neutral particle beam. For instance, the inspection tool 700 may include a transmission electron microscope (TEM) or a scanning electron microscope (SEM). For purposes of the present disclosure, it is noted herein the at least one inspection tool 700 may be a single inspection tool 700 or may represent a group of inspection tools 700.

It is noted herein the sample 702 may be a semiconductor wafer of a plurality of semicondcutor wafers, where each semicondcutor wafer of the plurality of semicondcutor wafers includes a plurality of layers, where each layer of the plurality of layers includes a plurality of semiconductor dies, where each semiconductor die of the plurality of semiconductor dies includes a plurality of blocks. In addition, it is noted herein the sample 702 may be a semiconductor die package formed from a plurality of semiconductor dies arranged in a 2.5D lateral combination of a bare die on a substrate inside an advanced die package or a 3D die package.

For the purposes of the present disclosure, the term “defect” may refer to a physical defect found by an inline inspection tool, a metrology measurement outlier, or other physical characteristic of the semiconductor device that is deemed to be an anomaly. A defect may be considered to be any deviation of a fabricated layer or a fabricated pattern in a layer from design characteristics including, but not limited to, physical, mechanical, chemical, or optical properties. In addition, a defect may be considered to be any deviation in alignment or joining of components in a fabricated semiconductor die package. Further, a defect may have any size relative to a semiconductor die or features thereon. In this way, a defect may be smaller than a semiconductor die (e.g., on the scale of one or more patterned features) or may be larger than a semiconductor die (e.g., as part of a wafer-scale scratch or pattern). For example, a defect may include deviation of a thickness or composition of a sample layer before or after patterning. By way of another example, a defect may include a deviation of a size, shape, orientation, or position of a patterned feature. By way of another example, a defect may include imperfections associated with lithography and/or etching steps such as, but not limited to, bridges between adjacent structures (or lack thereof), pits, or holes. By way of another example, a defect may include a damaged portion of a sample 702 such as, but not limited to, a scratch, or a chip. For instance, a severity of the defect (e.g., the length of a scratch, the depth of a pit, measured magnitude or polarity of the defect, or the like) may be of importance and taken into consideration. By way of another example, a defect may include a foreign particle introduced to the sample 702. By way of another example, a defect may be a misaligned and/or misjoined package component on the sample 702. Accordingly, it is to be understood that examples of defects in the present disclosure are provided solely for illustrative purposes and should not be interpreted as limiting.

In another non-limiting example, the one or more semiconductor fabrication subsystems 202 includes at least one metrology tool 704 (e.g., an inline sample analysis tool) for measuring one or more properties of the sample 702 or one or more layers thereof. For example, a metrology tool 704 may characterize properties such as, but not limited to, layer thickness, layer composition, critical dimension (CD), overlay, or lithographic processing parameters (e.g., intensity or dose of illumination during a lithographic step). In this regard, a metrology tool 704 may provide information about the fabrication of the sample 702, one or more layers of the sample 702, or one or more dies of the sample 702 that may be relevant to the probability of manufacturing defects that may lead to reliability issues for the resulting fabricated devices. For purposes of the present disclosure, it is noted herein the at least one metrology tool 704 may be a single metrology tool 704 or may represent a group of metrology tools 704.

In some embodiments, the one or more semiconductor fabrication subsystems 202 includes at least one semiconductor manufacturing tool or process tool 706. For example, the process tool 706 may include any tool known in the art including, but not limited to, an etcher, scanner, stepper, cleaner, or the like. For instance, a fabrication process may include fabricating multiple dies distributed across the surface of a sample (e.g., a semiconductor wafer, or the like), where each die includes multiple patterned layers of material forming a device component. Each patterned layer may be formed by the process tool 706 via a series of steps including material deposition, lithography, etching to generate a pattern of interest, and/or one or more exposure steps (e.g., performed by a scanner, a stepper, or the like). By way of another example, the process tool 706 may include any tool known in the art configured to package and/or combine semiconductor dies into a 2.5D and/or 3D semiconductor die package. For instance, a fabrication process may include, but is not limited to, aligning semiconductor dies and/or electrical components on the semiconductor dies. In addition, a fabrication process may include, but is not limited to, joining the semiconductor dies and/or the electrical components on the semiconductor dies via hybrid bonding (e.g., die-to-die, die-to-wafer, wafer-to-wafer, or the like) solder, an adhesive, fasteners, or the like. For purposes of the present disclosure, it is noted herein the at least one process tool 706 may be a single process tool 706 or may represent a group of process tools 706.

In a step 604, test measurements are acquired for one or more semiconductor dies on the one or more semiconductor devices. In some embodiments, the system 220 includes the one or more test tool subsystems 206 for testing the functionality of one or more portions of a manufactured device.

In one non-limiting example, the one or more test tool subsystems 206 may include any number or type of electrical test tools 708 to complete a preliminary probing at a wafer level. For example, the preliminary probing may not be designed to try to force a failure at the wafer level.

In another non-limiting example, the one or more test tool subsystems 206 may include any number or type of stress test tool 710 to test, inspect, or otherwise characterize the properties of one or more portions of a fabricated device at any point in the manufacturing cycle. For example, the stress test tool 710 may include, but is not limited to, a pre burn-in electrical wafer sort and final test (e.g., an e-test) or a post burn-in electrical test configured to heat the sample 702 (e.g., an oven or other heat source), cool the sample 702 (e.g., a freezer or other cold source), operate the sample 702 at an incorrect voltage (e.g., a power supply), or the like.

In some embodiments, defects are identified using any combination of characterization subsystems 204 (e.g., inspection tools 700, metrology tools 704, or the like), the test tool subsystems 206 (e.g., including electrical test tools 708 and/or stress test tools 710, or the like) after one or more processing steps (e.g., lithography, etching, aligning, joining, or the like) performed by one or more process tools 706 for layers of interest in the semiconductor dies and/or semiconductor die packages. In this regard, the defect detection at various stages of the manufacturing process may be referred to as inline defect detection.

In a step 606, the characterization measurements and the test measurements are automatically transmitted to a system for determining one or more gap areas in defect-based test coverage for the one or more semiconductor devices.

In some embodiments, the system 220 includes a controller 712. The controller 712 may include one or more processors 714 configured to execute program instructions maintained on memory 716 (e.g., a memory medium, memory device, or the like). Further, the controller 712 may be communicatively coupled with any of the components of the system 220 including, but not limited to, the inspection tools 700, the metrology tools 704, test tools 708 including electrical test tools 708 and/or stress test tools 710, the system 200, or the like.

One or more steps of the method or process 100 may be automatically performed. For example, the one or more processors 714 of the controller 712 may be configured to receive the information for characterization measurements performed on select semiconductor devices, determine one or more apparent killer defects from the information for inline inspection and metrology measurements, receive information for the test measurements taken for the select semiconductor devices, determine one or more semiconductor dies which pass select tests from the test measurements taken for the select semiconductor devices, correlate the information received for characterization measurements performed on select semiconductor devices with the information received for test measurements taken for the select semiconductor devices, determine one or more gap areas for defect-based test coverage from the correlated information, and/or determine one or more adjustments to the fabrication, characterizing, and/or testing of semiconductor devices based on the determined one or more gap areas. It is noted herein the one or more steps of the method or process 100 may be performed continuously as new data becomes constantly available from the characterization measurements.

The one or more processors 714 of the controller 712 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 714 of the controller 712 may include any device configured to execute algorithms and/or instructions (e.g., program instructions stored in memory). In one embodiment, the one or more processors 714 of the controller 712 may be embodied as a desktop computer, mainframe computer system, workstation, image computer, parallel processor, networked computer, or any other computer system configured to execute a program configured to operate or operate in conjunction with components of the system 200, as described throughout the present disclosure.

The memory 716 of the controller 712 may include any storage medium known in the art suitable for storing program instructions executable by the associated respective one or more processors 714 of the controller 712. For example, the memory 716 of the controller 712 may include a non-transitory memory medium. By way of another example, the memory 716 of the controller 712 may include, but is not limited to, a read-only memory (ROM), a random-access memory (RAM), a magnetic or optical memory device (e.g., disk), a magnetic tape, a solid-state drive and the like. It is further noted that the memory 716 of the controller 712 may be housed in a common controller housing with the one or more processors 714. In one embodiment, the memory 716 of the controller 712 may be located remotely with respect to the physical location of the respective one or more processors 714 of the controller 712. For instance, the respective one or more processors 714 of the controller 712 may access a remote memory (e.g., server), accessible through a network (e.g., internet, intranet, and the like).

In another embodiment, the system 220 includes a user interface 718 coupled (e.g., physically coupled, electrically coupled, communicatively coupled, or the like) to the controller 712. For example, the user interface 718 may be a separate device coupled to the controller 712. By way of another example, the user interface 718 and the controller 712 may be located within a common or shared housing. It is noted herein, however, the controller 712 may not include, require, or be coupled to the user interface 718.

The user interface 718 of the controller 712 may include, but is not limited to, one or more desktops, laptops, tablets, and the like. The user interface 718 of the controller 712 may include a display used to display data of the system 200 to a user. The display of the user interface 718 of the controller 712 may include any display known in the art. For example, the display may include, but is not limited to, a liquid crystal display (LCD), an organic light-emitting diode (OLED) based display, or a CRT display. Those skilled in the art should recognize that any display device capable of integration with a user interface 718 of the controller 712 is suitable for implementation in the present disclosure. In another embodiment, a user may input selections and/or instructions responsive to data displayed to the user via a user input device of the user interface 718 of the controller 712.

In a step 608, one or more control signals are generated for one or more adjustments based on the one or more gap areas in defect-based test coverage to at least one of the fabrication, characterizing, or testing of the one or more semiconductor devices. For example, the one or more control signals may adjust the one or more semiconductor fabrication subsystems 202 and/or the one or more fabrication processes or methods or the one or more characterization processes or methods employed by the one or more semiconductor fabrication subsystems 202, via either a feed forward loop (e.g., to correct current semiconductor devices) or a feedback loop (e.g., to adjust future semiconductor devices). By way of another example, the one or more control signals may adjust the one or more test tool subsystems 206 and/or the one or more testing processes or methods employed by the one or more test tool subsystems 206, via either a feed forward loop (e.g., to correct current semiconductor devices) or a feedback loop (e.g., to adjust future semiconductor devices).

Although embodiments of the present disclosure illustrate the steps of the methods or processes 100, 600 being performed by the controller 712, it is noted herein some or all of the steps of the methods or processes 100, 600 may be performed by a server or controller communicatively coupled to the controller 712. For example, the server or controller may include processors and memory, and other communicatively-coupled components as described throughout the present disclosure.

It is noted herein the embodiments illustrated in FIG. 7A and the embodiments illustrated in FIG. 7B may be considered parts of the same system 220, parts of different systems 220, or parts of different subsystems of the different systems 220, for purposes of the present disclosure. For example, where the system 220 includes inline characterization, the characterization tools 700, 704 and/or the process tools 706 may be organized to receive the sample 702 at different stages during the fabrication of the sample 702. In addition, it is noted herein components within the system 220 illustrated in FIG. 7A and components within the system 220 illustrated in FIG. 7B may be in direct communication or may communicate through the controller 712.

It is noted herein the methods or processes 100 and 600 are not limited to the steps and/or sub-steps provided. The methods or processes 100 and 600 may include more or fewer steps and/or sub-steps. The methods or processes 100 and 600 may perform the steps and/or sub-steps simultaneously. The methods or processes 100 and 600 may perform the steps and/or sub-steps sequentially, including in the order provided or an order other than provided. Therefore, the above description should not be interpreted as a limitation on the scope of the present disclosure but merely an illustration.

In this regard, the system 200 (and the system 220) and the method or process 100 may provide an economic tradeoff between testing time and number of semiconductor die returns due to gap areas in the defect-based test coverage. In addition, the system 200 (and the system 220) and the method or process 100 may provide a semiconductor fabricator with an accurate empirical picture of semiconductor die areas at elevated risk of reliability and/or a quantitative comparison among semiconductor device designs for percentage area of defect-based test coverage gaps.

For example, the system 200 (and the system 220) and the method or process 100 may provide an improved insight into baseline test coverage gaps will help enable automotive semiconductor device manufacturers to reduce reliability failures from the PPM to PPB range. Semiconductor failures are the number one failure item for automobile manufacturing, and the issue will become more intense as the semiconductor content for automobiles grows (e.g., with the implementation of autonomous driving and electric vehicles). Similarly, reliability concerns are also becoming increasingly important in industrial, biomedical, defense, aerospace, hyper-scale data centers, and the like. Identifying test coverage gaps will create awareness of the limitation of electrical test methods, and therefore drive the adoption of inline defect screening inspections to mitigate these problems.

In one non-limiting example, inline characterization may be performed at a select (e.g., critical) layer. At user-selectable time intervals (e.g., quarterly, monthly, weekly, or the like), the system 200 may generate reports for all semiconductor devices being monitored via one or more steps of the method or process 100 to provide a baseline of test coverage gaps across semiconductor devices. For example, the reports may alert if select areas of a semiconductor device have statistically elevated levels of apparent killer defects in semiconductor die that pass all tests. It is noted herein the report may be triggered automatically once pre-defined thresholds are reached. In addition, it is noted herein for devices under high scrutiny for reliability problems, reporting frequency may be increased to understand improvement over time. Further, it is noted herein design-of-experiment (DOE) studies may be performed to reduce test coverage gaps by altering the test protocol. Further, it is noted herein the system 200 may provide real-time feedback on the efficacy of such changes, allowing for the use of the system 200 and method or process 100 when qualifying new/future devices and/or during “safe launch” activities.

Advantages of the present disclosure are directed to systems and methods for automatically identifying defect-based test coverage gaps in semiconductor devices. In particular, advantages of the present disclosure are directed to allowing for the automatic identification of previously unknown locations within designs which have an elevated susceptibility to reliability escapes from killer defects in test gaps. Advantages of the present disclosure are also directed to using empirical defect data to systematically identify test coverage gaps. Advantages of the present disclosure are also directed to providing new metrics and/or charting to demonstrate continuous improvement, evaluate the effectiveness of test program changes, and quantify test gap differences on a device-by-device basis or between different devices in the product portfolio over time as improvements are made.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. A system comprising:
a controller communicatively coupled to one or more semiconductor fabrication subsystems and one or more test tool subsystems, the controller including one or more processors configured to execute program instructions causing the one or more processors to:
determine, via a characterization subsystem, a plurality of apparent killer defects on one or more semiconductor devices based on characterization measurements of the one or more semiconductor devices acquired by the one or more semiconductor fabrication subsystems, wherein the one or more semiconductor devices include a plurality of semiconductor dies;
determine, via a testing subsystem, at least one semiconductor die of the plurality of semiconductor dies which passes at least one test of a plurality of tests based on test measurements acquired by the one or more test tool subsystems;
correlate, via a correlation subsystem, the characterization measurements with the test measurements to determine at least one apparent killer defect of the plurality of apparent killer defects on the at least one semiconductor die of the plurality of semiconductor dies which passes the at least one test of the plurality of tests; and
determine, via a localization subsystem, one or more gap areas on the one or more semiconductor devices for defect-based test coverage based on the at least one apparent killer defect on the at least one semiconductor die of the plurality of semiconductor dies which passes the at least one test of the plurality of tests.

2. The system of claim 1, the one or more processors further configured to execute the program instructions causing the one or more processors to:
receive, via the characterization subsystem, the characterization measurements acquired by the one or more semiconductor fabrication subsystems during fabrication of the one or more semiconductor devices.

3. The system of claim 1, wherein the one or more characterization subsystems include one or more characterization tools configured to perform at least one of one or more inline defect inspection processes or one or more metrology processes.

4. The system of claim 1, wherein the characterization subsystem is configured to employ at least one of an advanced deep learning technique or a machine learning technique to determine the plurality of apparent killer defects on the one or more semiconductor devices based on the characterization measurements.

5. The system of claim 1, the one or more processors further configured to execute the program instructions causing the one or more processors to:
receive, via the testing subsystem, the test measurements for the one or more semiconductor devices acquired by the one or more test tool subsystems.

6. The system of claim 1, wherein the one or more test tool subsystems include one or more test tools configured to perform at least one of one or more electrical wafer sort processes, unit probe processes, class probe processes, or final test processes.

7. The system of claim 1, wherein the at least one semiconductor die of the plurality of semiconductor dies passes all tests of the plurality of tests.

8. The system of claim 1, wherein the localization subsystem analyzes at least one of a location or a frequency of the at least one apparent killer defect of the plurality of apparent killer defects on the at least one semiconductor die of the plurality of semiconductor dies which passes the at least one test of the plurality of tests.

9. The system of claim 1, the one or more processors further configured to execute the program instructions causing the one or more processors to:
generate one or more reports based on the one or more gap areas in defect-based test coverage on the one or more semiconductor devices.

10. The system of claim 9, wherein the one or more reports include at least one metric to adjust at least one of the one or more semiconductor fabrication subsystems or the one or more test tool subsystems to mitigate the one or more gap areas on the one or more semiconductor devices for defect-based test coverage.

11. The system of claim 9, wherein the one or more reports include at least one chart configured to evaluate the one or more gap areas on the one or more semiconductor devices for defect-based test coverage.

12. The system of claim 11, wherein the at least one chart is configured to compare a test cover gap trend over a range of time for a particular semiconductor device design.

13. The system of claim 11, wherein the at least one chart is configured to compare a test cover gap for multiple semiconductor device designs.

14. The system of claim 1, the one or more processors further configured to execute the program instructions causing the one or more processors to:
determine one or more adjustments to at least one of the fabrication, characterizing, or testing of the semiconductor devices based on the one or more gap areas on the one or more semiconductor devices for defect-based test coverage.

15. The system of claim 14, the one or more processors further configured to execute the program instructions causing the one or more processors to:
generate one or more control signals based on the one or more adjustments to at least one of the fabrication, characterizing, or testing of the semiconductor devices.

16. The system of claim 15, wherein the one or more control signals are configured to target select inline defect part average testing (I-PAT) care areas on the semiconductor devices.

17. A method comprising:
determining, via a characterization subsystem of a controller, a plurality of apparent killer defects on one or more semiconductor devices based on characterization measurements of the one or more semiconductor devices acquired by one or more semiconductor fabrication subsystems, wherein the one or more semiconductor devices include a plurality of semiconductor dies;
determining, via a testing subsystem of the controller, at least one semiconductor die of the plurality of semiconductor dies which passes at least one test of a plurality of tests based on test measurements acquired by one or more test tool subsystems;
correlating, via a correlation subsystem of the controller, the characterization measurements with the test measurements to determine at least one apparent killer defect of the plurality of apparent killer defects on the at least one semiconductor die of the plurality of semiconductor dies which passes the at least one test of the plurality of tests; and
determining, via a localization subsystem of the controller, one or more gap areas on the one or more semiconductor devices for defect-based test coverage based on the at least one apparent killer defect on the at least one semiconductor die of the plurality of semiconductor dies which passes the at least one test of the plurality of tests.

18. The method of claim 17, further comprising:
receiving, via the characterization subsystem of the controller, the characterization measurements acquired by the one or more semiconductor fabrication subsystems during fabrication of the one or more semiconductor devices.

19. The method of claim 17, wherein the one or more characterization subsystems include one or more characterization tools configured to perform at least one of one or more inline defect inspection processes or one or more metrology processes.

20. The method of claim 17, wherein the characterization subsystem is configured to employ at least one of an advanced deep learning technique or a machine learning technique to determine the plurality of apparent killer defects on the one or more semiconductor devices based on the characterization measurements.

21. The method of claim 17, further comprising:
receiving, via the testing subsystem of the controller, the test measurements for the one or more semiconductor devices acquired by the one or more test tool subsystems.

22. The method of claim 17, wherein the one or more test tool subsystems include one or more test tools configured to perform at least one of one or more electrical wafer sort processes, unit probe processes, class probe processes, or final test processes.

23. The method of claim 17, wherein the at least one semiconductor die of the plurality of semiconductor dies passes all tests of the plurality of tests.

24. The method of claim 17, wherein the localization subsystem analyzes at least one of a location or a frequency of the at least one apparent killer defect of the plurality of apparent killer defects on the at least one semiconductor die of the plurality of semiconductor dies which passes the at least one test of the plurality of tests.

25. The method of claim 17, further comprising:
generating, via the controller, one or more reports based on the one or more gap areas in defect-based test coverage on the one or more semiconductor devices.

26. The method of claim 25, wherein the one or more reports include at least one metric to adjust at least one of the one or more semiconductor fabrication subsystems or the one or more test tool subsystems to mitigate the one or more gap areas on the one or more semiconductor devices for defect-based test coverage.

27. The method of claim 25, wherein the one or more reports include at least one chart configured to evaluate the one or more gap areas on the one or more semiconductor devices for defect-based test coverage.

28. The method of claim 27, wherein the at least one chart is configured to compare a test cover gap trend over a range of time for a particular semiconductor device design.

29. The method of claim 27, wherein the at least one chart is configured to compare a test cover gap for multiple semiconductor device designs.

30. The method of claim 17, further comprising:
determining, via the controller, one or more adjustments to at least one of the fabrication, characterizing, or testing of the semiconductor devices based on the one or more gap areas on the one or more semiconductor devices for defect-based test coverage.

31. The method of claim 30, further comprising:
generating, via the controller, one or more control signals based on the one or more adjustments to at least one of the fabrication, characterizing, or testing of the semiconductor devices.

32. The method of claim 31, wherein the one or more control signals are configured to target select inline defect part average testing (I-PAT) care areas on the semiconductor devices.

33. A system comprising:
one or more semiconductor fabrication subsystems;
one or more test tool subsystems; and
a controller communicatively coupled to the one or more semiconductor fabrication subsystems and the one or more test tool subsystems, the controller including one or more processors configured to execute program instructions causing the one or more processors to:
determine, via a characterization subsystem, a plurality of apparent killer defects on one or more semiconductor devices based on characterization measurements of the one or more semiconductor devices acquired by the one or more semiconductor fabrication subsystems, wherein the one or more semiconductor devices include a plurality of semiconductor dies;
determine, via a testing subsystem, at least one semiconductor die of the plurality of semiconductor dies which passes at least one test of a plurality of tests based on test measurements acquired by the one or more test tool subsystems;
correlate, via a correlation subsystem, the characterization measurements with the test measurements to determine at least one apparent killer defect of the plurality of apparent killer defects on the at least one semiconductor die of the plurality of semiconductor dies which passes the at least one test of the plurality of tests; and
determine, via a localization subsystem, one or more gap areas on the one or more semiconductor devices for defect-based test coverage based on the at least one apparent killer defect on the at least one semiconductor die of the plurality of semiconductor dies which passes the at least one test of the plurality of tests.
